(19) United States
(12) Patent Application Publication
(10) Pub. No.: US 2025/0006800 A1
(43) Pub. Date: Jan. 2, 2025

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Bo-Jiun LIN, Hsinchu County (TW); Tsung-En LEE, Taipei City (TW); Tung Ying LEE, Hsinchu City (TW); Chao-Ching CHENG, Hsinchu City (TW)

(73) Assignee: TAIWAN SEMICONDUCTOR MANUFACTURING COMPANY, LTD., Hsinchu (TW)

(21) Appl. No.: 18/346,219

(22) Filed: Jul. 1, 2023

(51) Int. Cl. H01L 29/40; H01L 29/49; H01L 29/66; H10K 10/46

(52) U.S. Cl. CPC H01L 29/401; H01L 29/4908; H01L 29/66045; H01L 29/66969; H10K 10/474

(57) ABSTRACT

A method of forming a semiconductor device comprises the following steps. A dielectric layer is formed over a substrate. A 2D material layer is formed over the dielectric layer. An adhesion layer is formed over the 2D material layer. Source/drain electrodes are formed on opposite sides of the adhesion layer. A first high-k gate dielectric layer is formed over the adhesion layer, wherein the adhesion layer has a material different from a material of the first high-k gate dielectric layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a semiconductor device in various stages of fabrication in accordance with some embodiments of the present disclosure.

FIG. 1B illustrates a schematic view of a mono-layer of an example TMD in accordance with some example embodiments.

FIGS. 2A, 2B, 2C, 3, 4, 5, 6 and 7A are cross-sectional views of a semiconductor device in various stages of fabrication in accordance with some embodiments of the present disclosure.

FIG. 7B is a diagram showing an atomic layer deposition (ALD) process for forming a second high-k gate dielectric layer in accordance with some embodiments.

FIG. 7C is an X-ray photoelectron spectroscopy (XPS) spectra illustrating aspects of a surface chemistry after forming a second high-k gate dielectric layer according to some embodiments.

FIGS. 8A, 8B and 8C are cross-sectional views of semiconductor devices, respectively, in various stages of fabrication in accordance with some embodiments of the present disclosure.

FIGS. 9A-9C are enlarged views of a region in FIG. 8A in accordance with some embodiments.

FIG. 10A shows a transfer characteristic in accordance with an example and a comparative example.

FIG. 10B shows a transfer characteristic in accordance with examples.

FIG. 10C is a diagram showing threshold voltage V_{TH} (or V_{TG}) versus backgate voltage (V_{BG}) in accordance with examples.

FIGS. 11A and 11B are diagrams showing a dielectric constant (k value) of pure HfOₓ (which is unopded) and a dielectric constant (k value) of HZO versus applied voltage, respectively, in accordance with some embodiments.

FIG. 12A is a diagram showing equivalent effective dielectric constant (ε_{eff}) value versus physical thickness (tₒₓ) on one monolayer MoS₂ (1 L-MoS₂) in accordance with an example and comparative examples.

FIG. 12B is a diagram showing breakdown voltage (V_{BD}) versus effective oxide thickness (EOT) in accordance with an example and comparative examples.

FIG. 12C is a diagram showing gate leakage current (Jg) versus EOT in accordance with an example and comparative examples.

FIG. 12D is a diagram showing EOT versus thickness of a second high-k gate dielectric layer in accordance with an example.

FIG. 12E is a diagram showing gate leakage current (Jg) versus topgate voltage (V_{TG}) in accordance with an example.

FIG. 13A is a diagram showing hysteresis ΔV_{TH} versus overvoltage (Vₒᵥ), which is defined as a difference between a bias voltage (V_{TG}) and a breakdown voltage (V_{TH}), in accordance with examples.

FIG. 13B is a diagram showing drain current (I_{D}) and gate leakage current (I_{G}) versus topgate voltage (V_{TG}) in accordance with an example.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

In a recent development of a field effect transistor (FET), a channel region of the FET may be formed in a two dimensional (2D) material layer, which may provide the FET with improved performance (e.g. relative to FETs that are devoid of a 2D material layer). As used herein, consistent with the accepted definition within solid state material art, a “2D material” may refer to a crystalline material consisting of a single layer of atoms. As widely accepted in the art, “2D material” may also be referred to as a “monolayer” material. In this disclosure, “2D material” and “monolayer” material are used interchangeably without differentiation in meanings, unless specifically pointed out otherwise.

However, depositing a high-k dielectric layer on the 2D material layer starts with a poor nucleation of the high-k dielectric layer. For example, the high-k gate dielectric layer nucleates as discontinuous particles on a surface of the 2D material layer.

Embodiments of the present disclosure provide an adhesion layer to improve adhesion between a 2D material layer and a high-k gate dielectric layer since the adhesion layer is able to nucleate as a continuous film on a surface of the 2D material layer. The adhesion layer can improve formation of a high-k gate dielectric layer or a high-k gate dielectric stack over the 2D material layer to improve electrical characteristics, such as reduce Subthreshold Swing (SS) and reduce effective oxide thickness (EOT). An increased effective dielectric constant (ε_{eff}), an increased breakdown voltage (V_{BD}) and a reduced gate leakage (JG) are achieved as well.

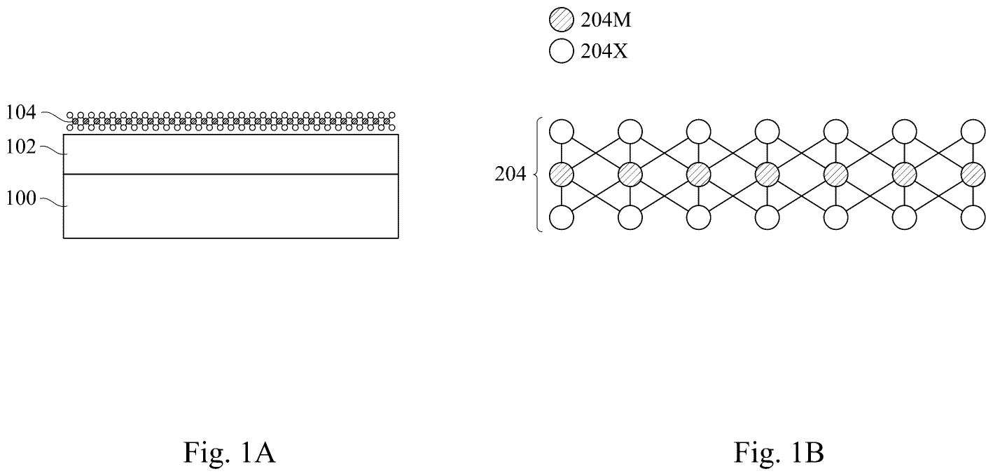

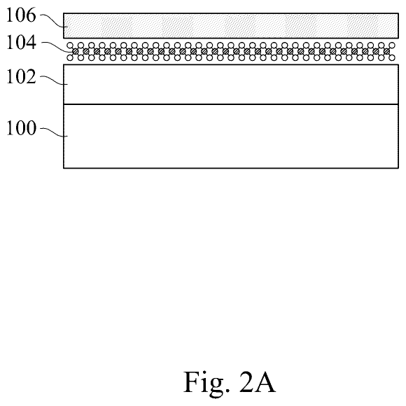

FIGS. 1A, 2A, 2B, 2C, 3, 4, 5, 6, 7A and 8A are cross-sectional views of a semiconductor device 10 in various stages of fabrication in accordance with some embodiments of the present disclosure. Reference is made to FIG. 1A. A dielectric layer 102 is formed on a substrate 100. The substrate 100 illustrated in FIG. 1A may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. In some embodiments, the substrate 100 is a silicon substrate doped with p-type dopants. Other substrates that may be used include multi-layered substrates, gradient substrates, or hybrid orientation substrates. In some embodiments, the substrate 100 has a thickness in a range from about 500 μm to about 600 μm, such as about 550 μm.

The dielectric layer 102 may be made of a nitride layer, such as SiNx or a silicon nitride-based material (e.g., SiON, SiCN or SiOCN). The dielectric layer 102 may be formed by chemical vapor deposition (CVD), including low pressure CVD (LPCVD) and plasma enhanced CVD (PECVD), physical vapor deposition (PVD), atomic layer deposition (ALD), or other suitable process. In some embodiments, the dielectric layer 102 has a thickness in a range from about 80 nm to about 120 nm, such as about 100 nm.

A 2D material layer 104 is formed over the dielectric layer 102. In some embodiments, the 2D material layer 104 is a 2D semiconductor layer, such as a carbon nanotube (CNT), graphene, transition metal dichalcogenide (TMD), the like, or a combination thereof. Formation of the 2D material layer 104 may include suitable processes. In some embodiments, the 2D material layer 104 includes a transition metal dichacogenide (TMD) monolayer material. In some embodiments, a TMD monolayer includes one layer of transition metal atoms sandwiched between two layers of chalcogen atoms. FIG. 1B illustrates a schematic view of a mono-layer 204 of an example TMD in accordance with some example embodiments. In FIG. 1B, the one-molecule thick TMD material layer includes transition metal atoms 204M and chalcogen atoms 204X. The transition metal atoms 204M may form a layer in a middle region of the one-molecule thick TMD material layer, and the chalcogen atoms 204X may form a first layer over the layer of transition metal atoms 204M, and a second layer underlying the layer of transition metal atoms 204M. The transition metal atoms 204M may be W atoms or Mo atoms, while the chalcogen atoms 204X may be S atoms, Se atoms, or Te atoms. In the example of FIG. 1B, each of the transition metal atoms 204M is bonded (e.g. by covalent bonds) to six chalcogen atoms 204X, and each of the chalcogen atoms 204X is bonded (e.g. by covalent bonds) to three transition metal atoms 204M. Throughout the description, the illustrated cross-bonded layers including one layer of transition metal atoms 204M and two layers of chalcogen atoms 204X in combination are referred to as a mono-layer 204 of TMD.

In some embodiment where the 2D material layer 104 includes TMD monolayers, the TMD monolayers include molybdenum disulfide (MoS₂), tungsten disulfide (WS₂), tungsten diselenide (WSe₂), or the like. In some embodiments, MoS₂ and WS₂ may be formed on the dielectric layer 102, using suitable approaches. For example, MoS₂ and WS₂ may be formed by micromechanical exfoliation and coupled over the dielectric layer 102, or by sulfurization of a pre-deposited molybdenum (Mo) film or tungsten (W) film over the dielectric layer 102. In alternative embodiments, WSe₂ may be formed by micromechanical exfoliation and coupled over the dielectric layer 102, or by selenization of a pre-deposited tungsten (W) film over the dielectric layer 102 using thermally cracked Se molecules.

In some other embodiments where MoS₂ is formed by micromechanical exfoliation, the 2D material layer 104 is formed on another substrate and then transferred to the dielectric layer 102. For example, a 2D material film is formed on a first substrate by chemical vapor deposition (CVD), sputtering or atomic layer deposition in some embodiments. A polymer film, such as poly(methyl methacrylate) (PMMA), is subsequently formed on the 2D material film. After forming the polymer film, the sample is heated, such as by placing the sample on a hot plate. Subsequent to heating, a corner of the 2D material film is peeled off the first substrate, such as by using a tweezers, and the sample is submerged in a solution to facilitate the separation of the 2D material film from the first substrate. The 2D material film and polymer film are transferred to the dielectric layer 102. The polymer film is then removed from the 2D material film using a suitable solvent.

In some embodiments where MoS₂ is formed by sulfurizing a pre-deposited molybdenum (Mo) film over the dielectric layer 102, a Mo film may be deposited over the dielectric layer 102, by suitable process, such as using RF sputtering with a molybdenum target to form the Mo film on the dielectric layer 102. After the Mo film is deposited, the substrate 100 as well as the Mo film are moved out of the sputtering chamber and exposed to air. As a result, the Mo film will be oxidized and form Mo oxides. Then, the sample is placed in the center of a hot furnace for sulfurization. During the sulfurization procedure, Ar gas is used as a carrier gas with the S powder placed on the upstream of the gas flow. The S powder is heated in the gas flow stream to its evaporation temperature. During the high-temperature growth procedure, the Mo oxide segregation and the sulfurization reaction will take place simultaneously. If the background sulfur is sufficient, the sulfurization reaction will be the dominant mechanism. Most of the surface Mo oxides will be transformed into MoS₂ in a short time. As a result, a uniform planar MoS₂ film will be obtained on the substrate after the sulfurization procedure. With this process, the 2D material layer 104 can be uniformly formed on a large-area of the dielectric layer 102.

In some embodiments, forming of the 2D material layer 104 also includes treating the 2D material layer 104 to obtain expected electronic properties of the 2D material layer 104. The treating processes include thinning (namely, reducing the thickness of the 2D material layer 104), doping, or straining, to make the 2D material layer 104 exhibit certain semiconductor properties, e.g., including direct bandgap. The thinning of the 2D material layer 104 may be achieved through various suitable processes, and all are included in the present disclosure. For example, plasma based dry etching, e.g., reaction-ion etching (RIE), may be used to reduce the number of monolayers of the 2D material layer 104. In the description hereinafter, the 2D material layer 104 may include semiconductor properties (interchangeably referred to as semiconductive 2D material layer in this context). In some cases, the 2D material layer 104 is a MoS₂ layer with a thickness in a range from about 0.5 nm to about 0.8 nm, such as about 0.7 nm.

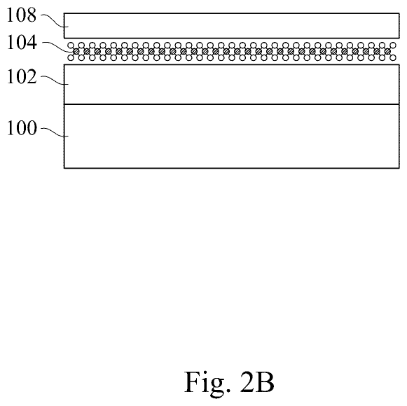

Reference is made to FIG. 2A. An adhesion layer 106 is formed on the 2D material layer 104 in some embodiments. The adhesion layer 106 may be in physical contact with the 2D material layer 104. In some embodiment, the adhesion layer 106 is a nanofog film or a nanofog oxide formed by a nanofog atomic layer deposition (ALD). In some embodiments, the adhesion layer 106 is a dielectric layer. In some embodiments, the adhesion layer 106 is a metal oxide layer or an aluminum-containing layer, such as aluminum oxide. For example, the adhesion layer 106 is sub-1 nm AlOₓ particles on a surface of the 2D material layer 104. In some embodiments, the adhesion layer 106 is formed by a nanofog ALD to provide uniform nucleation centers followed by performing a deposition process such as ALD or other deposition methods such as chemical vapor deposition (CVD), low pressure CVD (LPCVD), physical vapor deposition (PVD), plating, evaporation, ion beam, energy beam, the like, or a combination thereof to achieve a desired thickness. In some embodiments, the adhesion layer 106 is formed at a low temperature using ALD. In some cases, the adhesion layer 106 has a thickness in a range from about 0.8 nm to about 1.2 nm, such as about 1 nm.

The adhesion layer 106 may be formed by other suitable method. Reference is made to FIG. 2B. In some other embodiments, a metal layer 108 may be formed on the 2D material layer 104. For example, the metal layer 108 includes an Al layer and is formed by electron beam gun (E-Gun), PVD, CVD, evaporation, ion beam, energy beam, plating, or a combination thereof. Referring to FIG. 2C, an oxidation process S100 may then be performed to oxidize the metal layer 108 to form the adhesion layer 106 including AlOₓ. For example, the oxidation process S100 is performed in an ambient including ozone (O₃), H₂O₂, H₂O, N₂O, or NO.

In FIG. 3, a mask layer 110 is formed over the adhesion layer 106 and then patterned to expose the 2D material layer 104. In some embodiments, the mask layer 110 may be a photoresist material formed using a spin-on coating process, followed by patterning the photoresist material using suitable lithography techniques. For example, photoresist material is irradiated (exposed) and developed to remove portions of the photoresist material. In greater detail, a photomask (not shown) may be placed over the photoresist material, which may then be exposed to a radiation beam provided by a radiation source such as ultraviolet (UV) source, deep UV (DUV) source, extreme UV (EUV) source, and X-ray source. For example, the radiation source may be a mercury lamp having a wavelength of about 436 nm (G-line) or about 365 nm (I-line); a Krypton Fluoride (KrF) excimer laser with wavelength of about 248 nm; an Argon Fluoride (ArF) excimer laser with a wavelength of about 193 nm; a Fluoride (F₂) excimer laser with a wavelength of about 157 nm; or other light sources having an appropriate wavelength (e.g., below approximately 100 nm). In another example, the light source is an EUV source having a wavelength of about 13.5 nm or less. After the mask layer 110 is formed and patterned, the adhesion layer 106 is etched using the mask layer 110 as an etch mask, exposing the 2D material layer 104.

Reference is made to FIG. 4. An electrode layer 112 is formed on the mask layer 110 and the 2D material layer 104 such as using ALD, CVD, LPCVD, PVD, plating, evaporation, ion beam, energy beam, the like, or a combination thereof. In some embodiments, the electrode layer 112 includes metal such as aluminum (Al), copper (Cu), tungsten (W), gold (Au), the like, or a combination thereof. In some embodiments, the electrode layer 112 is conformally formed on the mask layer 110 and the 2D material layer 104.

In FIG. 5, the mask layer 110 is removed by using, for example, a lift-off process. Lifting off the mask layer 110 also removes an overlying portion of the electrode layer 112, thus leaving other portions of the electrode layer 112 on opposite sidewalls of the adhesion layer 106 to serve as source/drain electrodes 114. The source/drain electrodes 114 are connected to the adhesion layer 106. A top surface 106T of the adhesion layer 106 is lower than a top surface 106T of one of the source/drain electrodes 114 in some examples.

In FIG. 6, a first high-k gate dielectric layer 116 is formed on the source/drain electrodes 114 and the adhesion layer 106. For example, the first high-k gate dielectric layer 116 extends along a sidewall of the source/drain electrodes 114 to over a top surface of one of the source/drain electrodes 114. The adhesion layer 106 is in physical contact with the first high-k gate dielectric layer 116 in some embodiments. For example, the first high-k gate dielectric layer 116 extends along a top surface of the adhesion layer 106. The formation method of the first high-k gate dielectric layer 116 may include Molecular-Beam Deposition (MBD), ALD, PECVD, or the like. In some embodiments, the adhesion layer 106 has a dielectric constant lower than a dielectric constant of the first high-k gate dielectric layer 116. Throughout the description, the k value of silicon oxide (SiO₂), which is about 3.9, is used to distinguish low k values from high k values. Accordingly, the k values lower than 3.8 are referred to as low k values, and the respective dielectric materials are referred to as low-k dielectric materials. Conversely, the k values higher than 3.9 are referred to as high k values, and the respective dielectric materials are referred to as high-k dielectric materials.

In some embodiments, the first high-k gate dielectric layer 116 is a metal oxide layer or a hafnium-containing layer. In some embodiments, the first high-k gate dielectric layer 116 includes hafnium oxide (HfOₓ). In some embodiments, the formation of the adhesion layer 106, and formation of the first high-k gate dielectric layer 116 which follows, is an in-situ process, for example, performed within a processing system such as an ALD cluster tool. As such, the term “in-situ” may also generally be used to refer to processes in which the device or substrate being processed is not exposed to an external ambient (e.g., external to the processing system). In other words, in some embodiments, the first high-k gate dielectric layer 116 may be deposited subsequently, in-situ after deposition of the adhesion layer 106. That is, the first high-k gate dielectric layer 116 is formed on the adhesion layer 106 in an in-situ manner (i.e., without vacuum break).

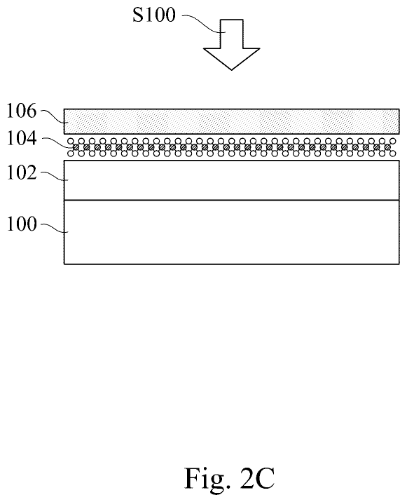

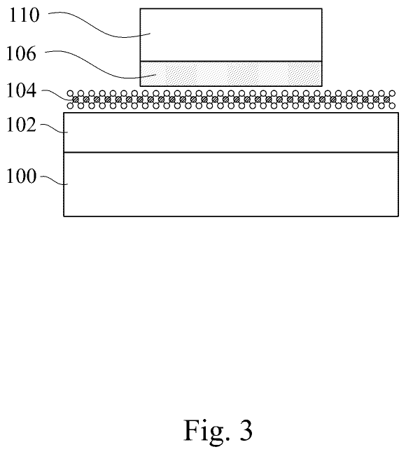

In FIG. 7A, a second high-k gate dielectric layer 118 is formed on the first high-k gate dielectric layer 116. The second high-k gate dielectric layer 118 and the first high-k gate dielectric layer 116 construct a high-k gate dielectric stack 119. The formation method of the second high-k gate dielectric layer 118 may include MBD, ALD, PECVD, or the like. In some embodiments, the second high-k gate dielectric layer 118 is a metal oxide layer or a hafnium-containing layer. In some embodiments, the second high-k gate dielectric layer 118 has a composition different from a composition of the first high-k gate dielectric layer 116. For example, the first high-k gate dielectric layer 116 is an undoped layer while the second high-k gate dielectric layer 118 is doped, for example, with zirconium.

In some embodiments, the second high-k gate dielectric layer 118 has a dielectric constant different from a dielectric constant of the first high-k gate dielectric layer 116. For example, the second high-k gate dielectric layer 118 has the dielectric constant greater than the dielectric constant of the first high-k gate dielectric layer 116. In some embodiments, the second high-k gate dielectric layer 118 includes hafnium zirconium oxide (HZO). For example, the second high-k gate dielectric layer 118 is HfₓZr_{y}O, in which a ratio of x to y is from about 1:1 to about 1:4. In some embodiments, the second high-k gate dielectric layer 118 is Hf_{0.3}Zr_{0.7}O₂. FIG. 7B is a diagram showing an ALD process for forming the second high-k gate dielectric layer 118 in accordance with some embodiments. Reference is made to FIGS. 7A and 7B. In some embodiments where the second high-k gate dielectric layer 118 is formed by ALD process, one or more first cycles S200 and one or more second cycles S202 are performed in the ALD process.

Each of the first cycles S200 includes steps S204 and S206. Each of the second cycles S202 includes steps S208 and S210. In the step S200, two half cycles (i.e., steps S204, S206) where one is a first metal organic precursor P1 pulse and another is an oxidant pulse are performed. The first metal organic precursor P1 including, for example, Hf precursor, such as Tetrakis(ethylmethylamido)hafnium (i.e., Hf[NCH₃C₂H₅]₄, TEMAH), is provided to chemisorb on a surface of the first high-k gate dielectric layer 116. The oxidant, such as water, reacts with the absorbed first metal organic precursor P1, forming a monolyaer of HfOₓ L_1. The TEMAH has the following formula (I):

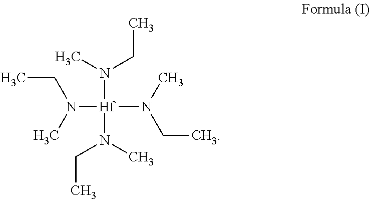

Further non-limiting examples of suitable tert-butoxide, HTB), Hf precursors include: Hf(O^{t}Bu)₄ (hafnium Hf(NEt₂)₄ (tetrakis(diethylamido)hafnium, TDEAH), Hf(NEtMe)₄ (tetrakis(ethylmethylamido)hafnium, TEMAH), Hf(NMe₂)₄ (tetrakis(dimethylamido)hafnium, TDMAH), Hf(mmp)₄ (hafnium methymethoxypropionate, Hf mmp), HfCl₄, (tetrakis(N,N′-dimethylacetamidinato)), Hf, Cp₂HfMe₂, Cp₂Hf(Me)OMe, (tBuCp)₂HfMe₂, CpHf(NMe₂)₃, and Hf(NiPr₂)₄. It is noted that Cp stands for cycclopentadienyl or alkylcyclopentadienyl; Me stands for methyl; Et stands for ethyl; and ⁱPr stands for iso-propyl. In the step S204, an unreactive inert gas, such as Ar or N₂, is used for purging away the excess first metal organic precursor P1 and the oxidant.

In the second cycles S202, two half cycles (i.e., steps 208, 210) where one is a second metal organic precursor P2 pulse and another is an oxidant pulse are performed. In the step S208, the second metal organic precursor P2 including, for example, Zr precursor, such as Tetrakis-(ethylmethylamino) zirconium (TEMAZ, Zr[N(C₂H₅)CH₃]₄) is provided to chemisorb on a surface of the monolayer of HfOₓ L_1 formed by the first cycle S200. The TEMAZ has the following formula (II):

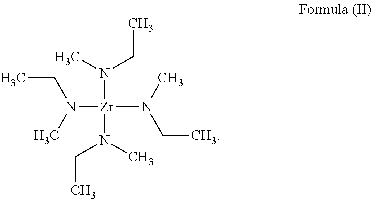

The oxidant, such as water, reacts with the absorbed second metal organic precursor P2, forming a monolyaer of ZrOₓ L_2. In the step S210, an unreactive inert gas, such as Ar or N₂, is used for purging away the excess second metal organic precursor P2 and the oxidant. In some embodiments, the steps S204, S206, S208 and S210 are repeated until a desired thickness is achieved. A ratio of the first cycles S200 and the second cycles S202 may be tuned to control an atomic ratio of Zr/Hf in the second high-k gate dielectric layer 118. For example, the first cycles S200 is performed for about X times, and the second cycles S202 are performed for about Y times.

In some embodiments, the second high-k gate dielectric layer 118 is formed by thermal ALD or plasma enhanced ALD (PEALD). FIG. 7C is an X-ray photoelectron spectroscopy (XPS) spectra illustrating aspects of a surface chemistry after forming the second high-k gate dielectric layer 118 according to some embodiments. Reference is made to FIGS. 7A-7C. Examples 1, 2 and 3 are shown in FIG. 7C. In some embodiments where the second high-k gate dielectric layer 118 is HfₓZr_{y}O, a Zr/Hf ratio in the second high-k gate dielectric layer 118 can be controlled by tuning a ratio of the first cycles S200 and the second cycles S202. In the example 1, the second high-k gate dielectric layer 118 is formed by PEALD using a ratio of the first cycles S200 and the second cycles S202 being about 1:2, and a Zr/Hf ratio of the second high-k gate dielectric layer 118 is about 2.32±0.2. The Zr in the second high-k gate dielectric layer 118 has an atomic ratio (%) of about 70±2%. In the example 2, the second high-k gate dielectric layer 118 is formed by thermal ALD, a ratio of the first cycles S200 and the second cycles S202 may be about 1:2, and a Zr/Hf ratio of the second high-k gate dielectric layer 118 is about 2.16±0.2. The Zr in the second high-k gate dielectric layer 118 has an atomic ratio (%) of about 68±2%. In the example 3, the second high-k gate dielectric layer 118 is formed by thermal ALD, a ratio of the first cycles S200 and the second cycles S202 may be about 1:4, and a Zr/Hf ratio of the second high-k gate dielectric layer 118 is about 4.47±0.2. The Zr in the second high-k gate dielectric layer 118 has an atomic ratio (%) of about 82±2%.

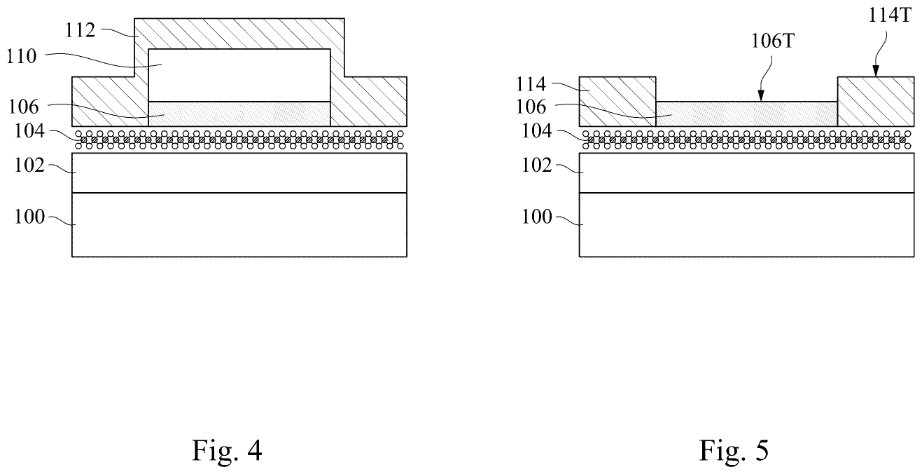

Reference is made to FIG. 8A. An electrode layer is formed on the second high-k gate dielectric layer 118, and a mask layer (not shown) may be formed on the electrode layer and patterned to expose the second high-k gate dielectric layer 118. In some embodiments, the mask layer may be a photoresist material formed using a spin-on coating process, followed by patterning the photoresist material using suitable lithography techniques. Details of the lithography techniques for the mask layer is similar to the mask layer 110 as discussed previously with regard to FIG. 3, and thus the description thereof is omitted herein. After the mask layer is formed and patterned, the electrode layer is etched using the mask layer as an etch mask, exposing the second high-k gate dielectric layer 118. The un-etched electrode layer serves as a gate electrode 120. A semiconductor device 10 is thus formed.

FIGS. 8B and 8C are cross-sectional views of semiconductor devices 10a, 10b, respectively, in various stages of fabrication in accordance with some embodiments of the present disclosure. Reference is made to FIG. 8B. The semiconductor device 10a is similar to the semiconductor device 10 of FIG. 8A, except for the second high-k gate dielectric layer 118 being absent between the gate electrode 120 and the adhesion layer 106.

Reference is made to FIG. 8C. The semiconductor device 10b is similar to the semiconductor device 10 of FIG. 8A, except for the first high-k gate dielectric layer 116 being absent between the gate electrode 120 and the adhesion layer 106. That is, the second high-k gate dielectric layer 118 is in contact with the adhesion layer 106. The second high-k gate dielectric layer 118 extends along a sidewall of the source/drain electrodes 114 to over the top surface of the source/drain electrodes 114.

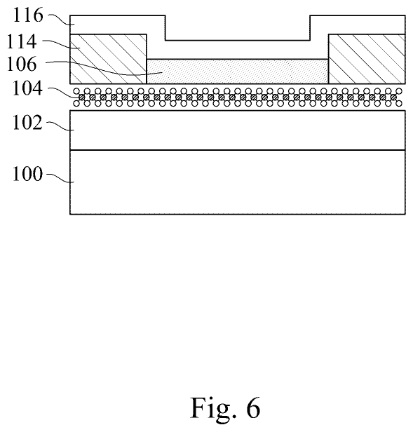

FIGS. 9A-9C are enlarged views of a region R1 in FIG. 8A in accordance with some embodiments. Reference is made to FIGS. 8A and 9A-9C. The high-k gate dielectric stack 119 can be characterized by an Energy dispersive spectroscopy (EDS) analysis by EDS mapping for Zr signal for the second high-k gate dielectric layer 118 and Al signal for the adhesion layer 106. Therefore, an observable boundary is between the adhesion layer 106 and the high-k gate dielectric stack 119 formed by the first and second high-k gate dielectric layers 116, 118. For example, in FIG. 9A, the adhesion layer 106 has a thickness t1 in a range from about 0.7 nm to about 1.3 nm, such as about 1 nm, and the high-k gate dielectric stack 119 has a thickness t2 in a range from about 4.5 nm to about 5.2 nm, such as about 4.9 nm. For example, in FIG. 9B, the adhesion layer 106 has a thickness t3 in a range from about 0.7 nm to about 1.3 nm, such as about 1 nm, and the high-k gate dielectric stack 119 has a thickness t4 in a range from about 3.5 nm to about 4.2 nm, such as about 3.9 nm. For example, in FIG. 9C, the adhesion layer 106 has a thickness t5 in a range from about 0.7 nm to about 1.3 nm, such as about 1 nm, and the high-k gate dielectric stack 119 has a thickness t6 in a range from about 2.1 nm to about 2.7 nm, such as about 2.4 nm.

### Example 4

A dielectric layer is formed on a substrate. A 2D material layer is formed on the dielectric layer. An adhesion layer is formed on the 2D material layer. Source/drain electrodes are formed on opposite sides of the adhesion layer. A first high-k gate dielectric layer and a second high-k gate dielectric layer are formed on the source/drain electrode and the adhesion layer in sequence, in which the first and second high-k gate dielectric layers include HfOₓ deposited under a temperature of 200±10° C. and 250±10° C., respectively. A gate electrode is formed on the second high-k gate dielectric layer.

### Comparative Example 1

A dielectric layer is formed on a substrate. A 2D material layer is formed on the dielectric layer. An adhesion layer is formed on the 2D material layer. Source/drain electrodes are formed on opposite sides of the adhesion layer. A first high-k gate dielectric layer is formed on the source/drain electrodes and the adhesion layer, in which the first high-k gate dielectric layer includes HfOₓ deposited under a temperature of 200±10° C. A gate electrode is formed on the first high-k gate dielectric layer.

### Example 5

A dielectric layer is formed on a substrate. A 2D material layer is formed on the dielectric layer. An adhesion layer is formed on the 2D material layer. Source/drain electrodes are formed on opposite sides of the adhesion layer. A first high-k gate dielectric layer and a second high-k gate dielectric layer are formed on the source/drain electrode and the adhesion layer in sequence, in which the first high-k gate dielectric layer includes HfOₓ deposited under a temperature of 200±10° C., and the second high-k gate dielectric layer includes HZO deposited under a temperature of 250±10° C. A gate electrode is formed on the second high-k gate dielectric layer.

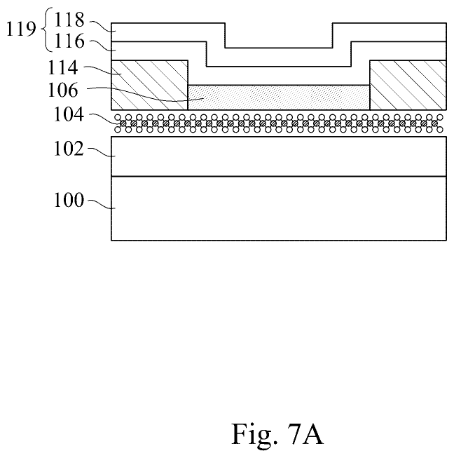

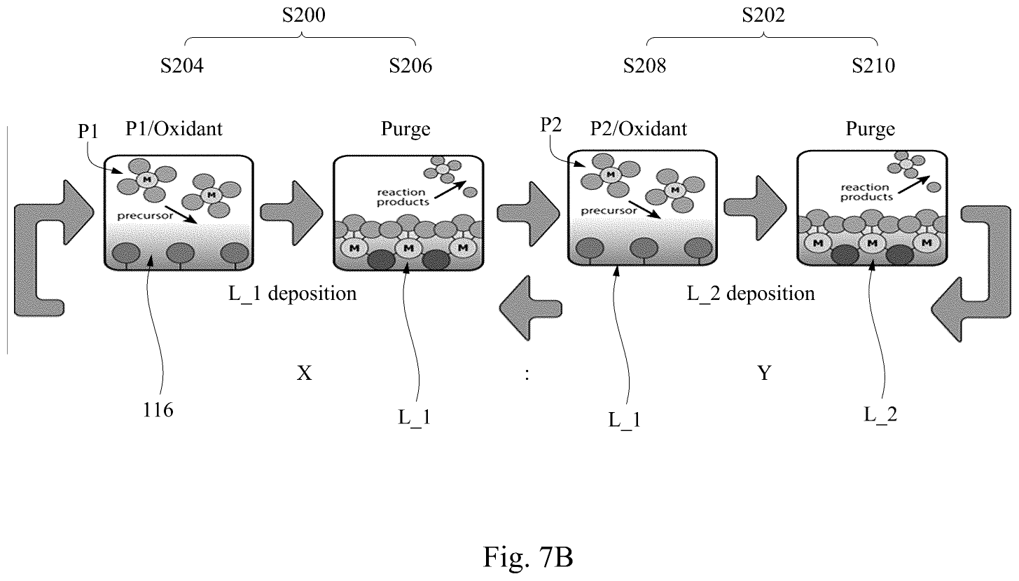

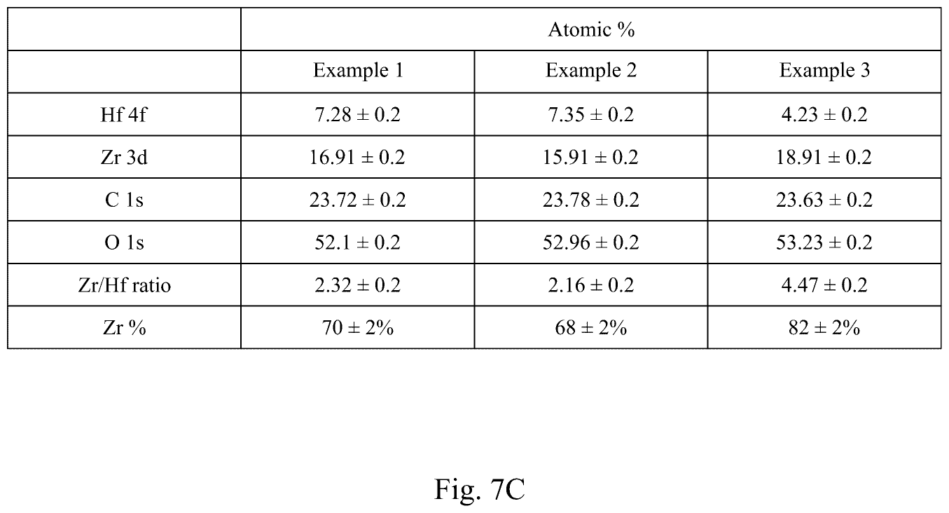

FIG. 10A shows a transfer characteristic in accordance with the example 4 and the comparative example 1. FIG. 10B shows a transfer characteristic in accordance with the example 4 and the example 5. A subthreshold slope (SS) is defined as mV of applied gate-voltage per decade of drain current change (mV/decade). As shown in FIG. 10A, the example 4 showed reduced subthreshold slope (SS), such as about 100±2 mV/dec. On the other hand, increased SS has been observed in the comparative example 1. As shown in FIG. 10B, the example 5 showed reduced subthreshold slope (SS), such as about 60±2 mV/dec.

FIG. 10C is a diagram showing threshold voltage V_{TH} (or V_{TG}) versus backgate voltage (V_{BG}) in accordance with the examples 4 and 5. As shown in FIG. 10C, the example 4 showed a reduced equivalent oxide thickness (EOT), such as an EOT of about 3.1±0.2 nm. The example 5 showed a reduced EOT as well, such as an EOT of about 2.2±0.2 nm.

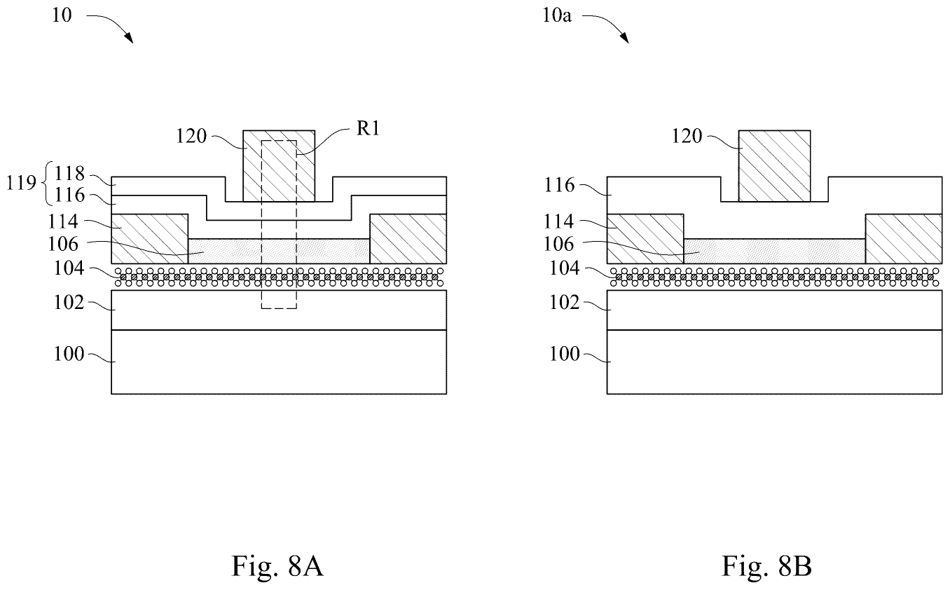

FIGS. 11A and 11B are diagrams showing a dielectric constant (k value) of the pure HfOₓ (which is unopded) and a dielectric constant (k value) of the HZO versus applied voltage, respectively, in accordance with some embodiments. In FIG. 11A, the dielectric constant of the pure HfOₓ is about 10±5, and in FIG. 11B, the dielectric constant of the HZO is about 24±5 which is greater than the dielectric constant of the pure HfOₓ.

### Example 6

A dielectric layer is formed on a substrate. One monolayer MoS₂ (1 L-MoS₂) is formed on the dielectric layer. An adhesion layer is formed on the monolayer MoS₂. Source/drain electrodes are formed on opposite sides of the adhesion layer. A first high-k gate dielectric layer and a second high-k gate dielectric layer are formed on the source/drain electrodes and the adhesion layer in sequence, in which the first high-k gate dielectric layer includes HfOₓ, and the second high-k gate dielectric layer includes HZO. A gate electrode is formed on the second high-k gate dielectric layer.

### Comparative Examples 2

A dielectric layer is formed on a substrate. One monolayer MoS₂ (1 L-MoS₂) is formed on the dielectric layer. Source/drain electrodes are formed on opposite sides of the monolayer MoS₂. A 3,4,9,10 perylenetetracarboxylic dianhydride (PTCDA) layer and a HfOₓ layer are formed on the source/drain electrodes in sequence. A gate electrode is formed on the HfOₓ layer.

### Comparative Example 3

A dielectric layer is formed on a substrate. One monolayer MoS₂ (1 L-MoS₂) is formed on the dielectric layer. Source/drain electrodes are formed on opposite sides of the monolayer MoS₂. An AlOₓ layer is formed on the source/drain electrodes. A gate electrode is formed on the AlOₓ layer.

### Comparative Example 4

A dielectric layer is formed on a substrate. One monolayer MoS₂ (1 L-MoS₂) is formed on the dielectric layer. Source/drain electrodes are formed on opposite sides of the monolayer MoS₂. An HfOₓ layer is formed on the source/drain electrodes. A gate electrode is formed on the HfOₓ layer.

### Comparative Example 5

A dielectric layer is formed on a substrate. One monolayer MoS₂ (1 L-MoS₂) is formed on the dielectric layer. Source/drain electrodes are formed on opposite sides of the monolayer MoS₂. A ZrOₓ layer is formed on the source/drain electrodes. A gate electrode is formed on the ZrOₓ layer.

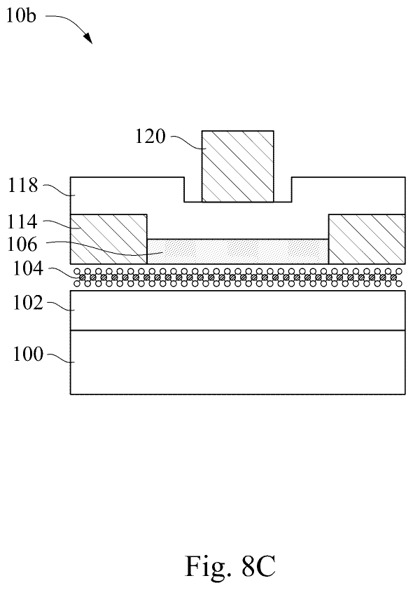

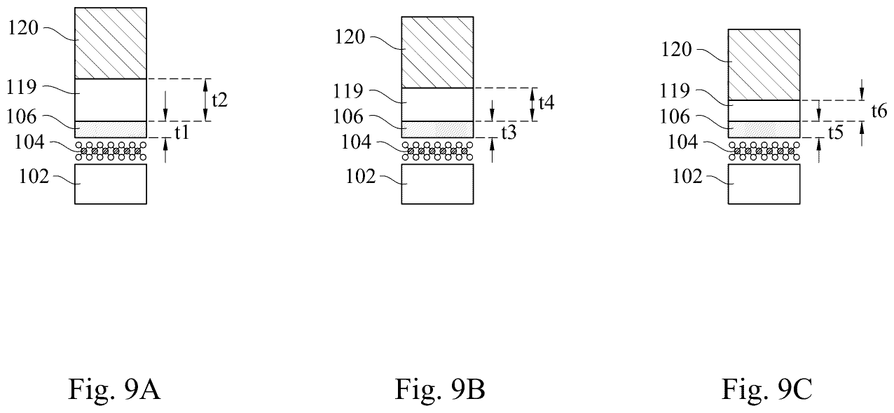

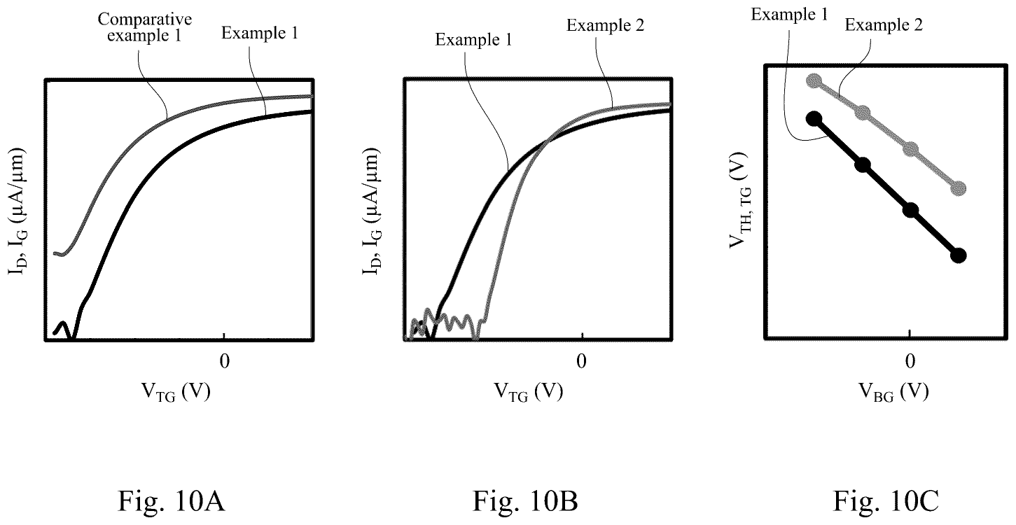

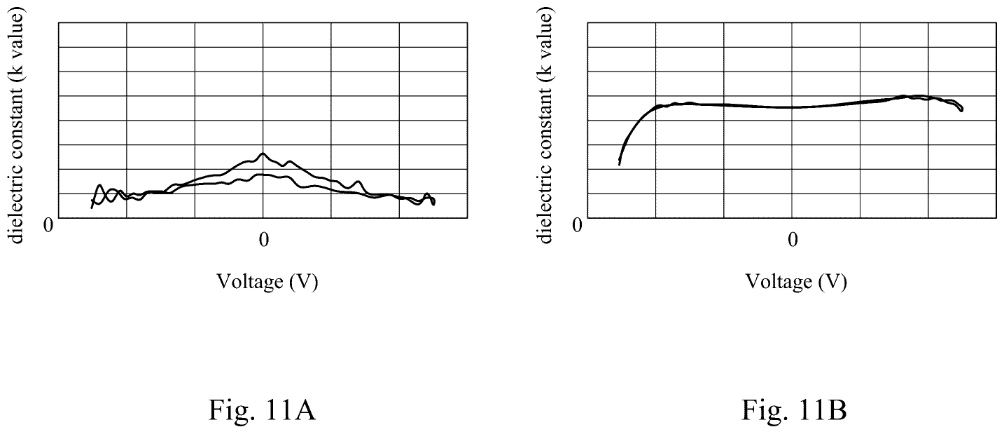

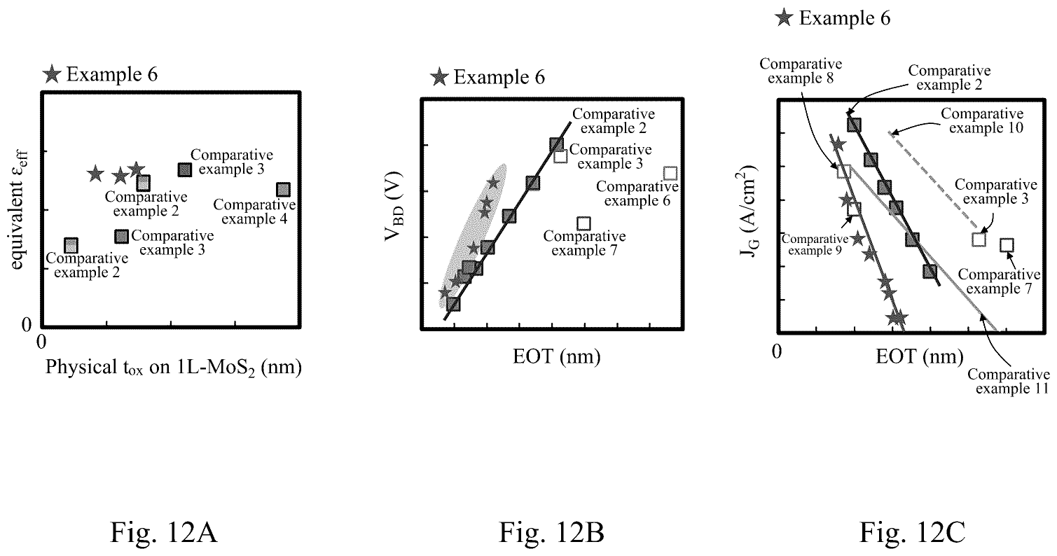

FIG. 12A is a diagram showing equivalent effective dielectric constant (ε_{eff}) value versus physical thickness (tₒₓ) on one monolayer MoS₂ (1 L-MoS₂) in accordance with the example 6 and the comparative examples 2, 3, 4 and 5. As shown in FIG. 12A, the example 6 showed an increased ε_{eff}. For example, the example 6 has ε_{eff} greater than ε_{eff} of the comparative examples 2, 3, 4 and 5.

### Comparative Example 6

A dielectric layer is formed on a substrate. One monolayer MoS₂ (1 L-MoS₂) is formed on the dielectric layer. Source/drain electrodes are formed on opposite sides of the one monolayer MoS₂. A YOₓ layer and a ZrOₓ layer are formed on the source/drain electrodes in sequence. A gate electrode is formed on the ZrOₓ layer.

### Comparative Example 7

A dielectric layer is formed on a substrate. One monolayer MoS₂ (1 L-MoS₂) is formed on the dielectric layer. Source/drain electrodes are formed on opposite sides of the monolayer MoS₂. A titanyl phthalocyanine (TiOPc) layer and an AlOₓ layer are formed on the source/drain electrodes in sequence. A gate electrode is formed on the ZrOₓ layer.

FIG. 12B is a diagram showing breakdown voltage (V_{BD}) versus effective oxide thickness (EOT) in accordance with the example 6 and comparative examples 2, 3, 6 and 7. As shown in FIG. 12B, the example 6 showed an increased V_{BD,} which is greater than V_{BD} of comparative examples 2, 3, 6 and 7. For example, the example 6 has a V_{BD} of about 12.4±2 MV/cm.

### Comparative Example 8

A dielectric layer is formed on a substrate in which the substrate is doped to serve as a back gate. A 2D material layer is formed on the dielectric layer. Source/drain electrodes are formed on opposite sides of the 2D material layer. A CaF₂ layer is formed on the source/drain electrodes and the 2D material layer.

### Comparative Example 9

A dielectric layer is formed on a substrate in which the substrate is doped to serve as a back gate. A 2D material layer is formed on the dielectric layer. Source/drain electrodes are formed on opposite sides of the 2D material layer. A SrTiO₃ layer is formed on the source/drain electrodes and the 2D material layer.

### Comparative Example 10

An HfOₓ layer is formed on a silicon substrate. Source/drain electrodes are formed on opposite sides of the HfOₓ layer. A gate electrode is formed on the HfOₓ layer.

### Comparative Example 11

An SiOₓ layer is formed on a silicon substrate. An HfOₓ layer is formed on the SiOₓ layer. Source/drain electrodes are formed on opposite sides of the HfOₓ layer. A gate electrode is formed on the HfOₓ layer.

FIG. 12C is a diagram showing gate leakage current (Jg) versus EOT in accordance with the example 6 and comparative examples 2, 3, 7, 8, 9, 10 and 11. As shown in FIG. 12C, the example 6 showed a reduced gate leakage current (Jg). which is lower than gate leakage current (Jg) of comparative examples 2, 3, 7, 8, 9, 10 and 11.

FIG. 12D is a diagram showing equivalent oxide thickness (EOT) versus thickness of the second high-k gate dielectric layer in accordance with the example 6. The second high-k gate dielectric layer of the example 6 showed a dielectric constant (k value) of about 24±2 with a thickness thereof in a range from about 3 nm to about 6 nm.

FIG. 12E is a diagram showing gate leakage current (Jg) versus topgate voltage (V_{TG}) in accordance with the example 6. In FIG. 12E, curves 1002 represent the second high-k gate dielectric layer of the example 6 with a thickness of about 1.5±0.2 nm. Curves 1004 represent the second high-k gate dielectric layer of the example 6 with a thickness of about 3±0.2 nm. In FIG. 12E, low gate leakage currents are achieved in curves 1002, 1004.

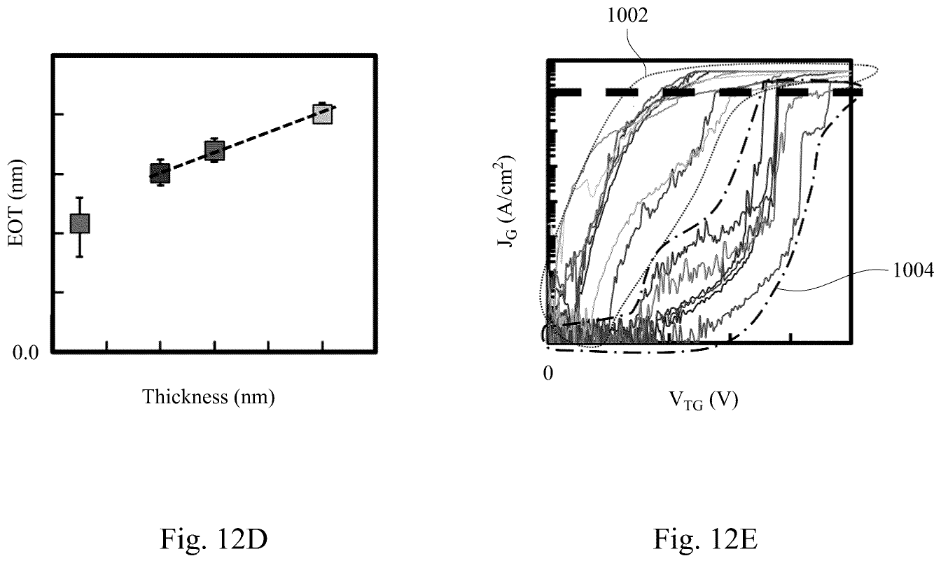

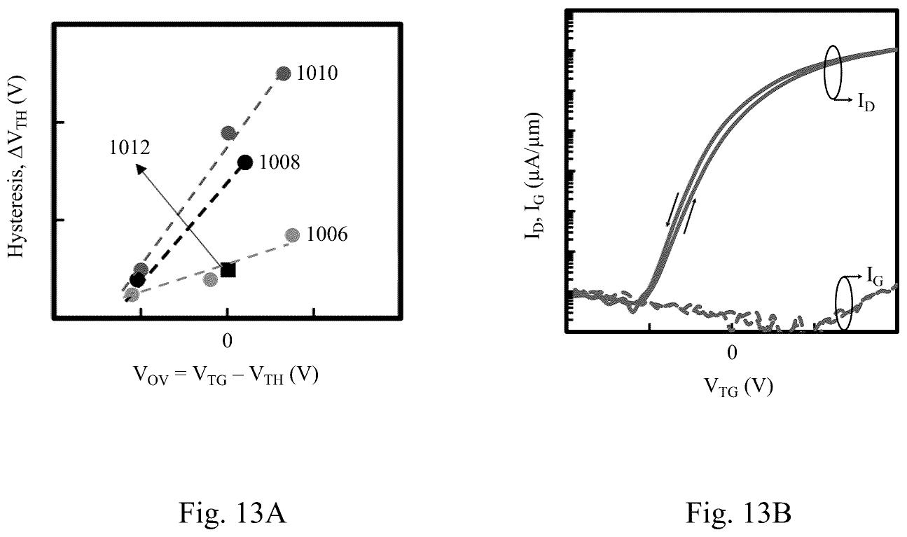

FIG. 13A is a diagram showing hysteresis ΔV_{TH} versus overvoltage (Vₒᵥ), which is defined as a difference between a bias voltage (V_{TG}) and a breakdown voltage (V_{TH}), in accordance with the examples 5 and 6. In FIG. 13A, symbols 1006, 1008 and 1010 represent the second high-k gate dielectric layer of the example 6 with a thickness of about 1.5±0.2 nm, 3±0.2 nm and 4±0.2 nm, respectively. Symbols 1012 represent the second high-k gate dielectric layer of the example 4 with a thickness of about 5±0.2 nm. As the thickness of the second high-k gate dielectric layer of the example 6 is reduced, ferroelectric characteristic thereof is quenched (or reduced) such that the ΔV_{TH} is reduced, resulting a nearly hysteresis-free second high-k gate dielectric layer.

FIG. 13B is a diagram showing drain current (I_{D}) and gate leakage current (I_{G}) versus topgate voltage (V_{TG}) in accordance with the example 6 with the second high-k gate dielectric layer with a thickness of about 1.5±0.2 nm. At a drain voltage (V_{D}) of about 1±0.2 V, the gate leakage current (I_{G}) is very low.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that an adhesion layer is formed to improve adhesion between a 2D material layer and a first high-k gate dielectric layer. Another advantage is that the adhesion layer improves formation of the first high-k gate dielectric layer and/or the second high-k gate dielectric layer on the 2D material layer to improve electrical characteristics, such as reduce Subthreshold Swing (SS) and reduce effective oxide thickness (EOT).

In some embodiments, a method of forming a semiconductor device comprises the following steps. A dielectric layer is formed over a substrate. A 2D material layer is formed over the dielectric layer. An adhesion layer is formed over the 2D material layer. Source/drain electrodes are formed on opposite sides of the adhesion layer. A first high-k gate dielectric layer is formed over the adhesion layer, wherein the adhesion layer has a material different from a material of the first high-k gate dielectric layer. In some embodiments, forming the adhesion layer on the 2D material layer comprises forming a nanofog film on the 2D material layer using atomic layer deposition. In some embodiments, forming the adhesion layer on the 2D material layer further comprises the following step. After forming the nanofog film on the 2D material layer using atomic layer deposition, a deposition process is performed to form a film on the nanofog film, the film having a material same as a material of the nanofog film. In some embodiments, the adhesion layer has a dielectric constant lower than a dielectric constant of the first high-k gate dielectric layer. In some embodiments, the adhesion layer is aluminum oxide. In some embodiments, the method further comprises forming a second high-k gate dielectric layer over the first high-k gate dielectric layer, wherein the second high-k gate dielectric layer has a composition different from a composition of the first high-k gate dielectric layer. In some embodiments, the second high-k gate dielectric layer has a dielectric constant greater than a dielectric constant of the first high-k gate dielectric layer. In some embodiments, the first high-k gate dielectric layer is hafnium oxide, and the second high-k gate dielectric layer is hafnium zirconium oxide. In some embodiments, forming the adhesion layer on the 2D material layer comprises the following steps. A metal layer is formed on the 2D material layer. The metal layer is oxidized to form the adhesion layer.

In some embodiments, a semiconductor device comprises a substrate, a dielectric layer over the substrate, a 2D material layer over the dielectric layer, an adhesion layer over the 2D material layer, a first hafnium-containing layer over the adhesion layer, wherein the first hafnium-containing layer has a dielectric constant higher than a dielectric constant of the adhesion layer, and source/drain electrodes over the 2D material layer. In some embodiments, the semiconductor device further comprises a second hafnium-containing layer over the first hafnium-containing layer, wherein the second hafnium-containing layer has a dielectric constant different from the dielectric constant of the first hafnium-containing layer. In some embodiments, the second hafnium-containing layer has the dielectric constant greater than the dielectric constant of the first hafnium-containing layer. In some embodiments, the first hafnium-containing layer is hafnium zirconium oxide. In some embodiments, the first hafnium-containing layer is an undoped layer. In some embodiments, a top surface of the adhesion layer is lower than a top surface of one of the source/drain electrodes. In some embodiments, the adhesion layer is in physical contact with the first hafnium-containing layer. In some embodiments, the first hafnium-containing layer extends along a sidewall of the source/drain electrodes to over a top surface of one of the source/drain electrodes.

In some embodiments, a method of forming a semiconductor device comprises the following steps. A nitride layer is formed over a semiconductor substrate. A 2D semiconductor layer is formed on the nitride layer. A first metal oxide layer is formed over the 2D semiconductor layer. The first metal oxide layer is patterned. A first deposition process is performed to form a second metal oxide layer on the first metal oxide layer. A gate electrode is formed over the second metal oxide layer. In some embodiments, the method further comprises after forming the first metal oxide layer, forming source/drain electrodes connected to the first metal oxide layer. In some embodiments, the method further comprises performing a second deposition process to form a third metal oxide layer on the second metal oxide layer, wherein the third metal oxide layer is doped with zirconium.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a dielectric layer over a substrate;
forming a 2D material layer over the dielectric layer;
forming an adhesion layer over the 2D material layer;
forming source/drain electrodes on opposite sides of the adhesion layer; and
forming a first high-k gate dielectric layer over the adhesion layer, wherein the adhesion layer has a material different from a material of the first high-k gate dielectric layer.

2. The method of claim 1, wherein forming the adhesion layer on the 2D material layer comprises:
forming a nanofog film on the 2D material layer using atomic layer deposition.

3. The method of claim 2, wherein forming the adhesion layer on the 2D material layer further comprises:
after forming the nanofog film on the 2D material layer using atomic layer deposition, performing a deposition process to form a film on the nanofog film, the film having a material same as a material of the nanofog film.

4. The method of claim 1, wherein the adhesion layer has a dielectric constant lower than a dielectric constant of the first high-k gate dielectric layer.

5. The method of claim 1, wherein the adhesion layer is aluminum oxide.

6. The method of claim 1, further comprising:
forming a second high-k gate dielectric layer over the first high-k gate dielectric layer, wherein the second high-k gate dielectric layer has a composition different from a composition of the first high-k gate dielectric layer.

7. The method of claim 6, wherein the second high-k gate dielectric layer has a dielectric constant greater than a dielectric constant of the first high-k gate dielectric layer.

8. The method of claim 6, wherein the first high-k gate dielectric layer is hafnium oxide, and the second high-k gate dielectric layer is hafnium zirconium oxide.

9. The method of claim 6, wherein forming the adhesion layer on the 2D material layer comprises:
forming a metal layer on the 2D material layer; and
oxidizing the metal layer to form the adhesion layer.

10. A semiconductor device, comprising:
a substrate;
a dielectric layer over the substrate;
a 2D material layer over the dielectric layer;
an adhesion layer over the 2D material layer;
a first hafnium-containing layer over the adhesion layer, wherein the first hafnium-containing layer has a dielectric constant higher than a dielectric constant of the adhesion layer; and
source/drain electrodes over the 2D material layer.

11. The semiconductor device of claim 10, further comprising:
a second hafnium-containing layer over the first hafnium-containing layer, wherein the second hafnium-containing layer has a dielectric constant different from the dielectric constant of the first hafnium-containing layer.

12. The semiconductor device of claim 11, wherein the second hafnium-containing layer has the dielectric constant greater than the dielectric constant of the first hafnium-containing layer.

13. The semiconductor device of claim 11, wherein the first hafnium-containing layer is hafnium zirconium oxide.

14. The semiconductor device of claim 11, wherein the first hafnium-containing layer is an undoped layer.

15. The semiconductor device of claim 11, wherein a top surface of the adhesion layer is lower than a top surface of one of the source/drain electrodes.

16. The semiconductor device of claim 11, wherein the adhesion layer is in physical contact with the first hafnium-containing layer.

17. The semiconductor device of claim 11, wherein the first hafnium-containing layer extends along a sidewall of the source/drain electrodes to over a top surface of one of the source/drain electrodes.

18. A method of forming a semiconductor device, comprising:
forming a nitride layer over a semiconductor substrate;
forming a 2D semiconductor layer on the nitride layer;
forming a first metal oxide layer over the 2D semiconductor layer;
patterning the first metal oxide layer;
performing a first deposition process to form a second metal oxide layer on the first metal oxide layer; and
forming a gate electrode over the second metal oxide layer.

19. The method of claim 18, further comprising:
after forming the first metal oxide layer, forming source/drain electrodes connected to the first metal oxide layer.

20. The method of claim 18, further comprising:
performing a second deposition process to form a third metal oxide layer on the second metal oxide layer, wherein the third metal oxide layer is doped with zirconium.
